(19) United States
(12) Patent Application Publication
(10) Pub. No.: US 2007/0194316 A1
(43) Pub. Date: Aug. 23, 2007

(54) DISPLAY APPARATUS

(75) Inventors: Joon-hoo CHOI, Seoul (KR); Byung-seong BAE, Asan City (KR); Kyu-ha CHUNG, Seoul (KR); Nam-deog KIM, Yongin-si (KR); Joon-chul GOH, Seoul (KR)

Correspondence Address: CANTOR COLBURN, LLP, 55 GRIFFIN ROAD SOUTH, BLOOMFIELD, CT, 06002, US

(73) Assignees: SAMSUNG ELECTRONICS CO., LTD, Suwon-si (KR); KYUNGHEE UNIVERSITY, Yongin-si (KR)

(21) Appl. No.: 11/676,789

(22) Filed: Feb. 20, 2007

(30) Foreign Application Priority Data
Feb. 20, 2006 (KR) 10-2006-0016081

(51) Int. Cl. H01L 29/00

(52) U.S. Cl. 257/69

(57) ABSTRACT

A display apparatus includes; a switching transistor, a driving transistor, a control terminal of which is connected to an output terminal of the switching transistor, a storage capacitor provided between the output terminal of the switching transistor and an output terminal of the driving transistor, and a complementary metal oxide semiconductor (“CMOS”) transistor connected in parallel with a control terminal of the switching transistor.

This application claims priority to Korean Patent Application No. 2006-0016081, filed on Feb. 20, 2006, and all the benefits accruing therefrom under 35 U.S.C. §119, the contents of which in its entirety are herein incorporated by reference.

### BACKGROUND OF INVENTION

1. Field of Invention

The present invention relates to a display apparatus, and more particularly, to a display apparatus supplying a stable driving voltage.

2. Description of the Related Art

Generally, an organic light emitting diode (“OLED”), which is one component of an OLED display, controls current flow to an organic light emitting layer to display an image. OLED displays are one type of a flat panel display. OLED displays have become popular due to their advantageous characteristics such as low driving voltage, light weight, slimness, wide viewing angle, high response speed, etc.

OLED displays comprise a plurality of pixels. To form one such pixel, an OLED substrate is provided with a switching transistor formed in an intersection of a gate line and a data line which is connected to a driving transistor which in turn is connected with a power supply line supplying a driving voltage. The driving transistor is in turn connected to a light emitting layer which emits varying amounts of light depending upon an amount of current passing therethrough. The amount of current supplied to an organic light emitting layer depends on a potential difference between a data voltage supplied from the switching transistor and the driving voltage supplied to the driving transistor.

Due to the relationship between light emitting intensity and voltage, a large magnitude data voltage is needed to produce a large amount of current in the light emitting layer in order to generate a higher intensity light. Unfortunately, an increase in the data voltage magnitude also increases the power consumption of the display.

To solve the above problem, the conventional OLED supplies a driving voltage to a driving transistor after a gate off voltage is supplied. However, it is difficult to independently control the driving voltage.

### BRIEF SUMMARY OF THE INVENTION

Accordingly, it is an aspect, feature and advantage of the present invention to provide a display apparatus which can decrease a required data voltage, and thereby reduce power consumption.

The foregoing and/or other aspects, features and advantages of the present invention can be achieved by providing an exemplary embodiment of a display apparatus which includes; a switching transistor, a driving transistor, a control terminal of which is connected to an output terminal of the switching transistor, a storage capacitor provided between the output terminal of the switching transistor and an output terminal of the driving transistor, and a complementary metal oxide semiconductor (“CMOS”) transistor connected in parallel with a control terminal of the switching transistor.

According to an exemplary embodiment of the present invention, the display apparatus further includes; a power supply line which supplies a driving voltage to the driving transistor, wherein the CMOS transistor includes a first transistor, and a second transistor connected in parallel with the first transistor, the first transistor is one of an n-type transistor and a p-type transistor, the second transistor is of a type opposite the first transistor, and the second transistor is connected in series with the driving transistor.

According to an exemplary embodiment of the present invention, the switching transistor includes an n-type transistor, and the second transistor turns off when a high voltage is supplied to the switching transistor.

According to an exemplary embodiment of the present invention, an input terminal of the second transistor is connected to the power supply line, and an output terminal thereof is connected to an input terminal of the driving transistor.

According to an exemplary embodiment of the present invention, the display apparatus further includes a pixel electrode, and a common electrode disposed substantially opposite the pixel electrode, wherein the first transistor is connected between the common electrode and the output terminal of the driving transistor.

According to an exemplary embodiment of the present invention, the display apparatus further includes a pixel electrode, and a common electrode disposed substantially opposite the pixel electrode, wherein an input terminal of the second transistor is connected to the output terminal of the driving transistor, and an output terminal of the second transistor is connected to the pixel electrode.

According to an exemplary embodiment of the present invention, the first transistor is connected between the output terminal of the driving transistor and the common electrode.

According to an exemplary embodiment of the present invention, the switching transistor includes a semiconductor layer including amorphous silicon.

According to an exemplary embodiment of the present invention, the switching transistor includes a semiconductor layer including polysilicon.

According to an exemplary embodiment of the present invention, the switching transistor includes a p-type transistor, and the second transistor turns off when a low voltage is supplied to the switching transistor.

According to an exemplary embodiment of the present invention, an input terminal of the second transistor is connected to the power supply line, and an output terminal thereof is connected to an input terminal of the driving transistor.

According to an exemplary embodiment of the present invention, the display apparatus further includes a pixel electrode, and a common electrode disposed substantially opposite the pixel electrode, wherein the first transistor is connected between the common electrode and the output terminal of the driving transistor.

According to an exemplary embodiment of the present invention, the display apparatus further includes a pixel electrode, and a common electrode disposed substantially opposite the pixel electrode, wherein an input terminal of the second transistor is connected to the output terminal of the driving transistor, and an output terminal of the second transistor is connected to the pixel electrode.

According to an exemplary embodiment of the present invention, the first transistor is connected between the output terminal of the driving transistor and the common electrode.

According to an exemplary embodiment of the present invention, the switching transistor includes a semiconductor layer including polysilicon.

In another exemplary embodiment of the present invention a display apparatus includes; a switching transistor, a driving transistor, a control terminal of which is connected to an output terminal of the switching transistor, a storage capacitor provided between the output terminal of the switching transistor and an output terminal of the driving transistor, and a first transistor and a second transistor respectively connected in parallel with a control terminal of the switching transistor, wherein the first transistor is one of an n-type transistor and a p-type transistor, and the second transistor is of a type opposite the first transistor.

According to an exemplary embodiment of the present invention, the display apparatus further includes a power supply line which supplies a driving voltage to the driving transistor, wherein the second transistor is connected in series with the driving transistor.

According to an exemplary embodiment of the present invention, the display apparatus further includes a pixel electrode, and a common electrode disposed substantially opposite the pixel electrode, wherein the first transistor is connected between the common electrode and the output terminal of the driving transistor.

In another exemplary embodiment of the present invention a method of manufacturing a display apparatus includes; forming a switching transistor, forming a driving transistor, a control terminal of which is connected to an output terminal of the switching transistor, forming a storage capacitor provided between the output terminal of the switching transistor and an output terminal of the driving transistor, and forming a complementary metal oxide semiconductor transistor connected in parallel with a control terminal of the switching transistor.

### BRIEF DESCRIPTION OF THE DRAWINGS

The above and/or other aspects, features and advantages of the prevent invention will become apparent and more readily appreciated from the following description of the exemplary embodiments, taken in conjunction with the accompanying drawings, in which:

FIG. 1 is an equivalent circuit diagram of a first exemplary embodiment of a display apparatus according to the present invention;

FIG. 2 is an output waveform diagram of the first exemplary embodiment of a display apparatus in FIG. 1;

FIG. 3 is a cross-sectional view of the first exemplary embodiment of a display apparatus of FIG. 1;

FIG. 4 is an equivalent circuit diagram of a second exemplary embodiment of a display apparatus according the present invention;

FIG. 5 is an equivalent circuit diagram of a third exemplary embodiment of a display apparatus according to the present invention;

FIG. 6 is an output waveform diagram of the third exemplary embodiment of a display apparatus of FIG. 5;

FIG. 7 is a cross-sectional view illustrating the third exemplary embodiment of display apparatus of FIG. 5; and

FIG. 8 is an equivalent circuit diagram of a fourth exemplary embodiment of a display apparatus according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in more detail with reference to the accompanying drawings.

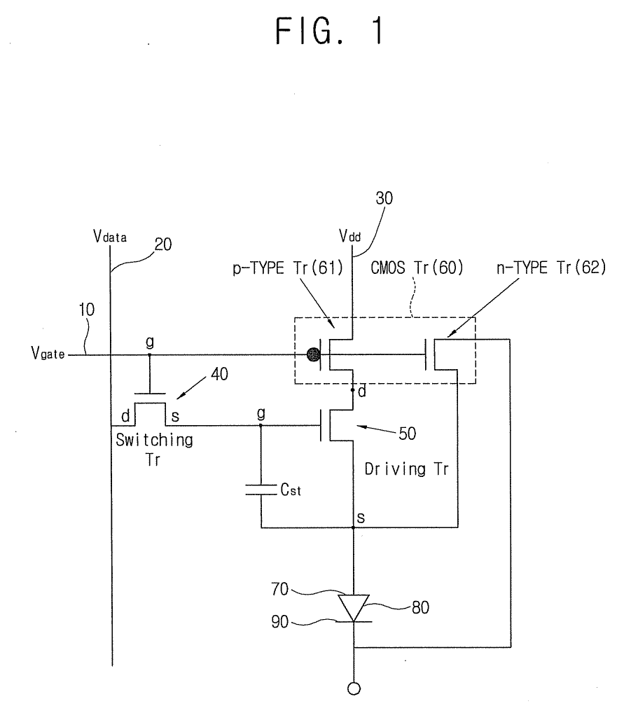

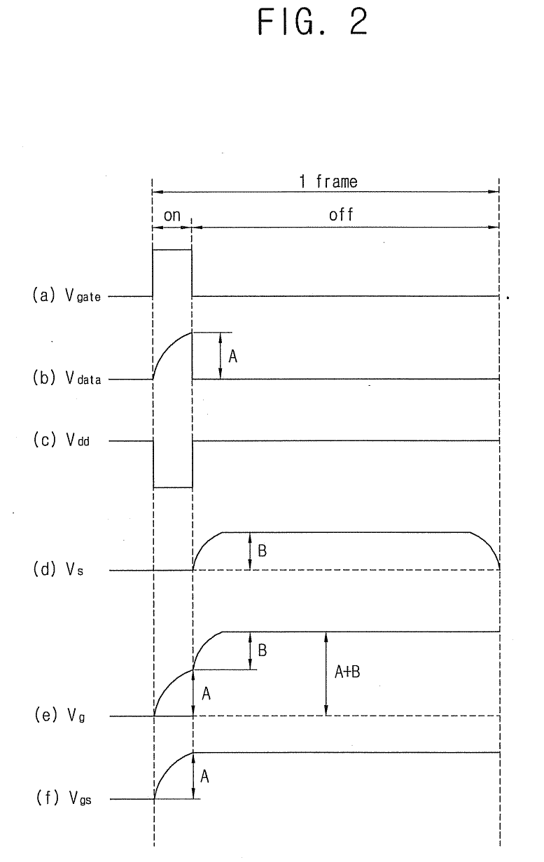

As shown in FIGS. 1 and 2, a first exemplary embodiment of a display apparatus according to the present invention includes an organic light emitting diode (“OLED”) with an organic light emitting layer.

The display apparatus includes a plurality of pixels. Each pixel of the display apparatus is supplied with a plurality of driving signals from a plurality of signal lines. The signal lines include a gate line 10, a data line 20 and a power supply line 30. The display apparatus includes a plurality of transistors 40, 50 and 60 connected with the signal lines 10, 20 and 30, and includes a pixel electrode 70 connected with a driving transistor 50, a common electrode 90 corresponding to the pixel electrode 70, and an organic light emitting layer 80 formed between electrodes 70 and 90.

The transistors 40, 50 and 60 include a switching transistor 40 connected to the gate line 10 and the data line 20, a driving transistor 50 connected with the switching transistor 40, and a complementary metal oxide semiconductor (“CMOS”) transistor 60 between the driving transistor 50 and the power supply line 30 and connected in parallel to the gate line 10. A storage capacitor Cₛₜ is formed between the switching transistor 40 and the driving transistor 50 to maintain a pixel voltage supplied to the pixel electrode 70.

The gate line 10 is but one of a plurality of gate lines running substantially parallel throughout the display apparatus. Similarly the data line 20 and the power supply line 30 are part of a plurality of data lines 20 and supply lines 30, respectively, which all are substantially parallel to one another and are substantially perpendicular to the plurality of gate lines.

The area between adjacent gate lines 10 and adjacent data lines 20 and power supply lines 30 defines one pixel. The gate line 10 supplies a gate on/off voltage V_{gate} to the switching transistor 40 connected thereto. The data line 20 supplies a data voltage V_{data} to the switching transistor 40. The power supply line 30 supplies a stable driving voltage to the driving transistor 50.

A gate metal layer forms gate electrodes g of the gate line 10 and the transistors 40, 50 and 60. In one exemplary embodiment the gate metal layer may be provided as a single layer or in alternative exemplary embodiments the gate metal layer may include multiple layers.

A data metal layer forms drain electrodes d and source electrodes s of the data line 20 and the transistors 40, 50 and 60. The data metal layer is insulated from the gate metal layer.

The power supply line 30, which runs substantially parallel with the data line 20, crosses the gate line 10 to form a pixel having a matrix shape. In one exemplary embodiment the power supply line 30 and the data line 20 are formed in the same data metal layer.

The switching transistor 40 includes the gate electrode g forming a part of the gate line 10, the drain electrode d branching from the data line 20, the source electrode s opposing the drain electrode d, and a semiconductor layer formed between the drain electrode d and the source electrode s. A gate on voltage supplied to the gate line 10 is transmitted to the gate electrode g of the switching transistor 40. When the gate on voltage is supplied to the gate electrode g the data voltage V_{data} supplied from the data line 20 is drained to the source electrode s via the drain electrode d. The drain electrode d receiving the data voltage V_{data} is referred to as an input terminal, the source electrode s is referred to as an output terminal, and the gate electrode g controlling input thereof is referred to as a control terminal.

In the present exemplary embodiment the switching transistor 40 is provided as an n-type transistor. In the n-type transistor, an n-type impurity is doped to a semiconductor layer contacting the source electrode s and the drain electrode d. The n-type transistor is turned on when voltage greater than a predetermined level is supplied to a gate electrode thereof. Thus, in the first exemplary embodiment of a display apparatus according to the present invention, a large magnitude voltage is supplied as the gate on voltage. In one exemplary embodiment the gate on voltage is about 20 V to about 30 V.

The CMOS transistor 60 includes a p-type transistor 61 and an n-type transistor 62, and the respective transistors 61 and 62 are connected with the gate line 10. N-type and p-type transistors differ from each other in the type and structure of the dopant in their semiconductor layers. The transistors 61 and 62 are connected in parallel with the control terminal g of the switching transistor 40. The gate voltage V_{gate} supplied from the gate line 10 is simultaneously supplied to the control terminals g of the p-type transistor 61 and the n-type transistor 62 as well as the control terminal g of the switching transistor 40. Referring to FIG. 1, the reference symbol ‘’ is added to the p-type transistor 61 to distinguish the p-type transistor 61 from the n-type transistor 62.

The p-type transistor 61 is connected in series with the driving transistor 50 and is disposed between the power supply line 30 and the driving transistor. The control terminal g of the n-type transistor 62 is connected to the gate line 10, and the input terminal d and the output terminal s thereof are respectively connected between the common electrode 90 and the driving transistor 50.

In the p-type transistor 61, a p-type impurity is doped to a semiconductor layer contacting the source electrode s and the drain electrode d. Therefore, if a voltage is supplied to the gate electrode g, a p channel is formed in the semiconductor layer. The p-type transistor 61 has electrical characteristics opposite to that of the n-type transistor 62. Thus, the p-type transistor 61 is turned on when voltage having less than a predetermined level is supplied to its gate electrode.

That is, if a high voltage is supplied along the gate line 10 the switching transistor 40 is turned on thereby and the p-type transistor 61 is turned off thereby. If a low voltage is supplied along the gate line 10 the p-type transistor 61 is turned on thereby. Thus, although the gate on voltage is supplied, the driving voltage will not be supplied to the driving transistor 50 connected in series with the p-type transistor 61 because the p-type transistor 61 is turned off, effectively blocking the voltage from the power supply line 30.

However, when a high voltage is supplied along the gate line 10 the n-type transistor 62 of the CMOS transistor 60 is turned on. If the n-type transistor 62 is turned on, the driving transistor 50 will be connected with the common electrode 90 through the n-type transistor 62. Therefore, a common voltage supplied to the common electrode 90 is supplied to the source electrode s of the driving transistor 50.

If a low voltage is supplied as a gate off voltage after the gate on voltage, the p-type transistor 61 is turned on and the n-type transistor 62 is turned off, and accordingly, the driving voltage V_{dd} is transmitted to the driving transistor 50.

The use of the CMOS transistor makes controlling the driving voltage V_{dd} to be supplied to the driving transistor 50 unnecessary during the gate on voltage.

In the conventional display apparatus, half of one frame is used for charging the data voltage V_{data} in the storage capacitor Cₛₜ, and the driving voltage V_{dd} is supplied to the organic light emitting diode 80 during the remaining half of the frame. Accordingly, light is essentially emitted only during half the frame.

However, in the first exemplary embodiment of a display apparatus according to the present invention, since the CMOS transistor 60 is connected to the gate line 10, supply of the driving voltage V_{dd} can be automatically determined according to the gate voltage V_{gate}, thereby maximizing a light emitting time of the pixel. Also, it is unnecessary to separately control an on or off voltage of the driving voltage V_{dd} every frame.

Since the driving transistor 50 is connected in series with the p-type transistor 61, the driving transistor 50 receives the driving voltage through the p-type transistor 61, and supplies a predetermined pixel voltage to the pixel electrode 70, wherein the predetermined voltage is based on the received driving voltage V_{dd} and the data voltage supplied to the gate electrode g. That is, the driving transistor 50 adjusts current between the drain electrode d and the source electrode s by means of the data voltage V_{data} supplied to the gate electrode g thereof. Voltage supplied to the pixel electrode 70 through the source electrode s corresponds to a difference between the data voltage V_{data} supplied to the gate electrode g and the driving voltage V_{dd} supplied to the drain electrode d.

If a high voltage is supplied as the gate on voltage, since the p-type transistor 61 is turned off and the n-type transistor 62 is turned on, voltage having the same level as voltage supplied to the common electrode 90 is supplied to the source electrode s of the driving transistor 50. In one exemplary embodiment the common electrode 90 is connected to a ground terminal. In another exemplary embodiment the common electrode 90 is supplied with a constant voltage such as a negative voltage, or other voltage level. Thus, voltage measured at the source electrode s of the driving transistor 50 maintains a constant level of voltage equal to the common voltage until the p-type transistor is turned on by supplying a gate off voltage to the gate line 10.

The storage capacitor Cₛₜ is provided between the driving transistor 50 and the output terminal s of the switching transistor 40. The storage capacitor Cₛₜ maintains the data voltage V_{data} as applied from the data line 20. In the conventional display apparatus, a storage capacitor Cₛₜ is formed between an output terminal of the switching transistor, and a power supply line or the ground terminal. Thus, a gate voltage V_{g} applied to a driving transistor varies according to the source voltage Vₛ of the driving transistor. On the other hand, in the first exemplary embodiment of a display apparatus according to the present invention, since the storage capacitor Cₛₜ is connected between the output terminal s of the driving transistor 50 and the output terminal s of the switching transistor 40, the difference between the gate voltage V_{g} and the source voltage Vₛ of the driving transistor 50 can be constantly maintained.

The gate voltage V_{g} and the source voltage Vₛ of the driving transistor 50 satisfy the following equation.

ΔV_{g}=C₁*ΔVₛ−Cₜₒₜₐₗ Equation 1

Cₜₒₜₐₗ refers to a total capacitance formed around the gate electrode g and the source electrode s of the driving transistor 50, and C₁ refers to capacitance directly connected to the gate electrode g and the source electrode s of the driving transistor 50. Here, since Cₜₒₜₐₗ and C₁ are equal to the storage capacitance Cₛₜ, ΔV_{g}=ΔVₛ is satisfied.

The difference between the gate voltage V_{g} and the source voltage Vₛ of the driving transistor 50, also known as V_{gs}, satisfies the following equation.

V_{gs}=V_{g}−Vₛ=V_{g}′+ΔV_{g}−ΔVₛ=V_{g}′(V_{g}=V_{g}′+ΔV_{g}) Equation 2

The gate voltage V_{g} of the driving transistor 50 corresponds to the sum of an initial gate voltage V_{g}′ and a change in gate voltage ΔV_{g}, which varies according to the input/output of the driving transistor 50, and if a source voltage variation ΔVₛ is subtracted therefrom, the difference V_{gs} between the gate voltage V_{g} and the source voltage Vₛ of the driving transistor 50 maintains its initial gate voltage V_{g}′. Thus, if voltage of the source electrode s varies by an amount from 0 to A, the gate voltage V_{g} will also vary from V_{g}′ to V_{g}′+A.

The intensity of light emitted by the organic light emitting layer 80 is controlled by the amount of current flow in the organic light emitting layer 80. The more current which flows therein, the more efficiently the organic light emitting layer 80 can emit light. Current flow in the organic light emitting layer 80 is proportionate to the difference between the gate voltage V_{g} and the source voltage Vₛ of the driving transistor 50, and the difference becomes larger as the gate voltage V_{g} of the driving transistor 50 increases.

In the conventional display apparatus, the gate voltage V_{g} of the driving transistor is the data voltage V_{data} transmitted through the switching transistor 40. However, in the first exemplary embodiment of a display apparatus according to the present invention, the gate voltage V_{g} of the driving transistor 50 proportionately increases with respect to the variation of the source voltage Vₛ of the driving transistor 50. Thus, in comparison with the conventional display apparatus, more current can be supplied to the organic light emitting layer 80, and thereby the required data voltage V_{data} may be decreased and power consumption of the exemplary embodiment of a display apparatus may be reduced.

Hereinafter, an operation of the first exemplary embodiment of a display apparatus according to the present invention will be described by referring to FIG. 2.

Referring to the signal shown in part (a) of FIG. 2, in one frame, a high voltage is supplied as the gate on voltage for a predetermined period of time. Referring to the signal shown in part (b) of FIG. 2, the data voltage V_{data} is transmitted to the switching transistor 40 by means of the gate on voltage, and charges the output terminal s of the switching transistor 40.

Referring to the signal shown in part (c) of FIG. 2, the p-type transistor 61 is turned off when the gate on voltage is supplied thereto. Thus, the driving voltage V_{dd} supplied from the power supply line 30 is supplied to the driving transistor 50 after the gate on voltage is turned off.

Referring to the signal shown in part (d) of FIG. 2, the source voltage Vₛ of the driving transistor 50 is maintained to have substantially the same voltage as the common electrode 90 (in the present exemplary embodiment the voltage of the common electrode 90 is approximately ground level) by means of the n-type transistor 62 during the gate on time period, and has a predetermined level B supplied by the p-type transistor 61 after the driving voltage V_{dd} is supplied.

Referring to the signal shown in part (e) of FIG. 2, the gate voltage V_{g} of the driving transistor 50 is charged to have a predetermined level A corresponding to the data voltage V_{data} during the gate on time period, and increases in response to the variation of the source voltage Vₛ of the driving transistor 50 when the gate off time period begins.

Referring to the signal shown in parts (g) and (f) of FIG. 2, after the gate off time period begins, the gate voltage V_{g} of the driving transistor 50 maintains a voltage A+B, and accordingly, the gate-source voltage V_{gs}, which influences the amount of current in the organic light emitting layer 80, maintains a voltage A.

The first exemplary embodiment of a display apparatus according to the present invention increases the gate voltage V_{g} of the driving transistor 50 so that it is proportional to the variation of the source voltage Vₛ of the driving transistor by means of the storage capacitor Cₛₜ. As described above with respect to FIG. 1, the storage capacitor Cₛₜ is provided between the gate electrode g of the driving transistor 50, the source electrode s of the switching transistor 40, and the source electrode s of the driving transistor 50. The display apparatus can automatically turn the driving voltage V_{dd} on and off in the pixel through the operation of the CMOS transistor 60 without varying the driving voltage supplied to the driving voltage line 30.

The pixel electrode 70 is provided as an anode to supply a hole to the organic light emitting layer 80.

In one exemplary embodiment the common electrode 90 is provided on a side of a display area of the display apparatus opposite the pixel electrode 70, and current from the pixel electrode passes through the organic light emitting layer 80 and is drained through the common electrode 90.

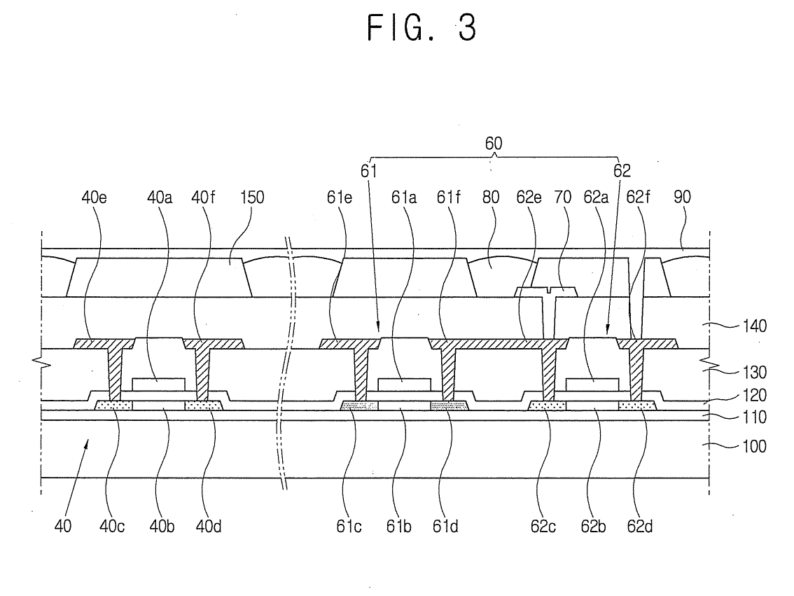

FIG. 3 is a cross-sectional view of the first exemplary embodiment of the display apparatus of FIG. 1, illustrating the switching transistor 40 and the CMOS transistor 60.

As shown in FIG. 3, a buffer layer 110 is formed on an insulated substrate 100, and a plurality of semiconductor layers 40b, 40c, 40d, 61b, 61c, 61d, 62b, 62c and 62d are disposed on the buffer layer 110. In one exemplary embodiment the buffer layer 110 includes silicon oxide, and prevents alkali metals, and other similar substances from infiltrating into the semiconductor layers 40b, 40c, 40d, 61b, 61c, 61d, 62b, 62c and 62d.

The semiconductor layers 40b, 40c, 40d, 61b, 61c, 61d, 62b, 62c and 62d include channel layers 40b, 61b and 62b which are not doped with an ion, and impurity layers 40c, 40d, 61c, 61d, 62c and 62d doped with a high ion concentration which are disposed on the opposite sides of the channel layers 40b, 61b and 62b with respect to each other.

In one exemplary embodiment the semiconductor layers 40b, 40c, 40d, 61b, 61c, 61d, 62b, 62c and 62d include poly silicon. In one exemplary embodiment the polysilicon may be obtained by crystallizing a patterned amorphous silicon. Exemplary embodiments of the crystallizing method include solid phase crystallization, laser crystallization, rapid thermal annealing, and various other methods. The solid phase crystallization may obtain polysilicon having a large crystal grain by performing a long heat treatment at temperatures below 600° C. Laser crystallization obtains polysilicon by using a laser; the laser crystallization may include an excimer laser annealing and sequential lateral solidification, or other similar techniques. The rapid thermal annealing deposits amorphous silicon at a low temperature, and applies a rapid heat treatment to a surface thereof with light.

The impurity layers 40c, 40d, 62c and 62d of the switching transistor 40 (which is an n-type transistor) and the n-type transistor 62 of the CMOS transistor 60 are doped with an ion including an element from group 5 of the periodic table such as phosphorus P, and the impurity layers 61c and 61d of the p-type transistor 61 of the CMOS transistor 60 are doped with an ion including an element from group 3 of the periodic table such as boron B.

A gate insulation layer 120, exemplary embodiments of which are formed of silicon oxide or silicon nitride, is disposed on the semiconductor layers 40b, 40c, 40d, 61b, 61c, 61d, 62b, 62c and 62d.

The gate electrodes 40a, 61a and 62a of the transistors 40, 61 and 62, respectively, are formed above the channel layers 40b, 61b and 62b and the gate insulation layer 120, and an inter-insulation layer 130 is provided over the gate insulation layer 120 to cover the gate electrodes 40a, 61a and 62a. Contact holes are formed in the gate insulation layer 120 and the inter-insulation layer 130 to expose the impurity layers 40c, 40d, 61c, 61d, 62c and 62d.

Source electrodes 40e, 61e and 62e and drain electrodes 40f, 61f and 62f are connected with the impurity layers 40c, 40d, 61c, 61d, 62c and 62d through the contact holes. The source electrodes 40e, 61e and 62e and drain electrodes 40f, 61f and 62f interpose the gate electrodes 40a, 61a and 62a therebetween are formed on the inter-insulation layer 130. The drain electrode 61f of the p-type transistor 61 and the source electrode 62e of the n-type transistor are interposed between both channel layers 61b and 62b of the transistors 61 and 62.

The inter-insulation layer 130, the source electrodes 40e, 61e and 62e, and the drain electrodes 40f, 61f and 62f are covered with an organic layer 140 formed with contact holes to expose the drain electrode 62f and the source electrode 62e of the n-type transistor 62.

The pixel electrode 70, one exemplary embodiment of which is formed of indium tin oxide (“ITO”) or indium zinc oxide (“IZO”) or an electric conductor having reflectivity, is formed on the organic layer 140 to be connected with the source electrode 62e of the n-type transistor 62 through at least one of the contact holes.

Partitions 150 are formed above the transistors 40, 61 and 62. Exemplary embodiments of the partitions 150 include an organic substance. The organic light emitting layers 80 are formed in pixel areas partitioned by the partitions 150.

The common electrode 90 is formed on the organic light emitting layers 80 and the partitions 150 to supply an electron to the organic light emitting layers 80. The drain electrode 62f of the n-type transistor 62 is connected with the common electrode 90 through at least one of the contact holes.

In one alternative exemplary embodiment, the first exemplary embodiment of a display apparatus according to the present invention includes a lightly doped domain (“LDD”) construction. In the LDD construction the semiconductor layers 40b, 40c, 40d, 61b, 61c, 61d, 62b, 62c and 62d, which are made of polysilicon, are divided into a first domain not doped with an ion, a second domain doped with an ion of high concentration and a third domain doped with an ion of low concentration to enhance an electrical property and to minimize a leakage current when the gate electrodes 40a, 61a and 62a are turned off.

Also, in one exemplary embodiment, the semiconductor layers 40b, 40c, 40d, 61b, 61c, 61d, 62b, 62c and 62d may include amorphous silicon instead of polysilicon.

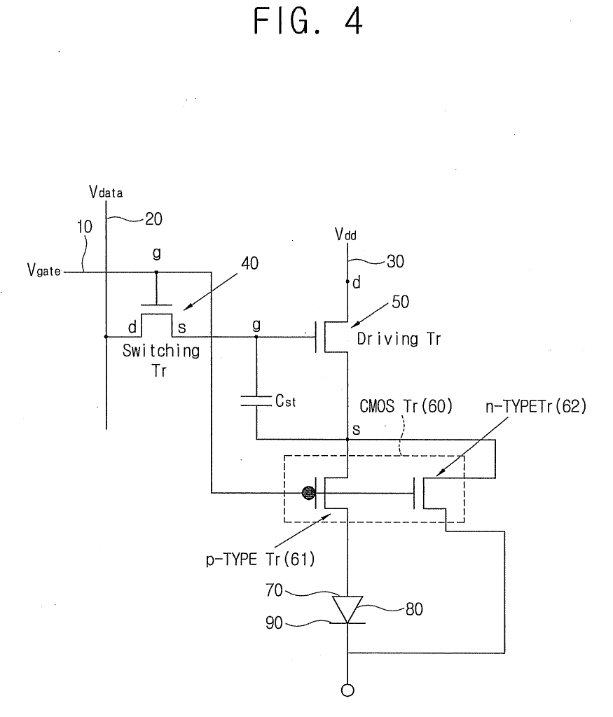

Hereinafter, a second exemplary embodiment of a display apparatus according to the present invention will be described with reference to FIG. 4.

As shown in FIG. 4, a second exemplary embodiment of a display apparatus according to the present invention includes a p-type transistor 61 connected between a driving transistor 50 and a pixel electrode 70, and an n-type transistor 62 connected between a source electrode s of the driving transistor 50 and a common electrode 90.

In the present exemplary embodiment, if a gate on voltage is supplied to a switching transistor 40, the n-type transistor 62 is turned on, and voltage of the common electrode 90 is supplied to the source electrode s of the driving transistor 50. If a gate off voltage is supplied to the switching transistor 40, the p-type transistor 61 will be turned on, and a driving voltage V_{dd} will be transmitted to the driving transistor 50.

When the gate on voltage is supplied and the n-type transistor 62 is turned on, the driving transistor 50 and the n-type transistor 62 act similar to resistors between a power supply line 30 and the common electrode 90. Thus, in one exemplary embodiment the channel of the n-type transistor 62 is widened to minimize the resistance thereof. Accordingly, a large amount of current can flow through the wide channel so that substantially all of a common voltage can be supplied to the output terminal s of the driving transistor 50.

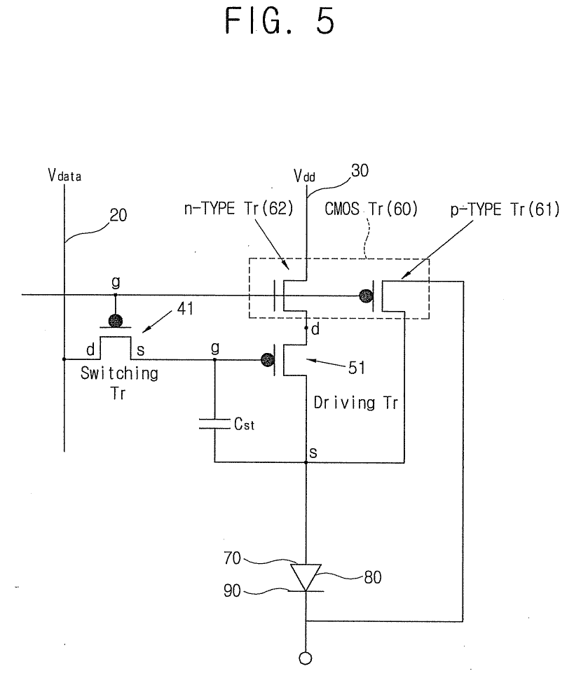

Hereinafter, a third exemplary embodiment of a display apparatus according to the present invention will be described with reference to FIGS. 5 to 7.

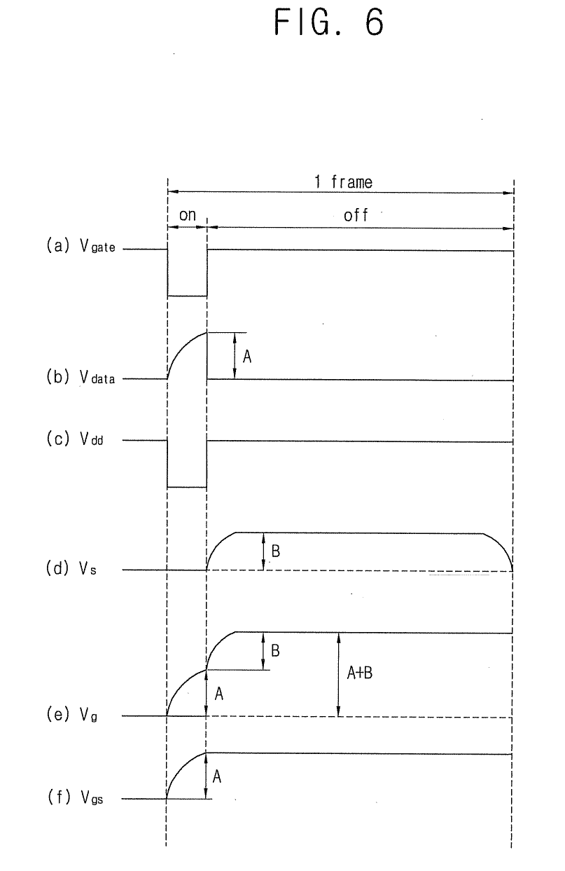

As shown in FIGS. 5 and 6, a third exemplary embodiment of a display apparatus according to the present invention includes a p-type switching transistor 41 and a p-type driving transistor 51. Thus, if a low voltage is supplied as a gate on voltage, the switching transistor 41 is turned on so that a data voltage V_{data} is supplied to a pixel.

An n-type transistor 62 of a CMOS transistor 60 is connected to a power supply line 30, and an output terminal s thereof is connected to an input terminal d of the driving transistor 51. If the switching transistor 41 is turned on, the n-type transistor 62 is turned off. Thus, a driving voltage V_{dd} can be prevented from being supplied to the driving transistor 51, and a common voltage can be supplied to an output terminal s of the driving transistor 51 by means of a p-type transistor 61. Essentially, the positioning of the respective p-type transistor 61 and n-type transistor 62 of the CMOS transistor 60 have been reversed from that shown in FIG. 1.

Referring to FIG. 6, waveforms of the respective voltages according to the third exemplary embodiment of the present invention have the same shapes as waveforms in FIG. 2 except that the on and off voltages of the gate voltage V_{gate} have been reversed.

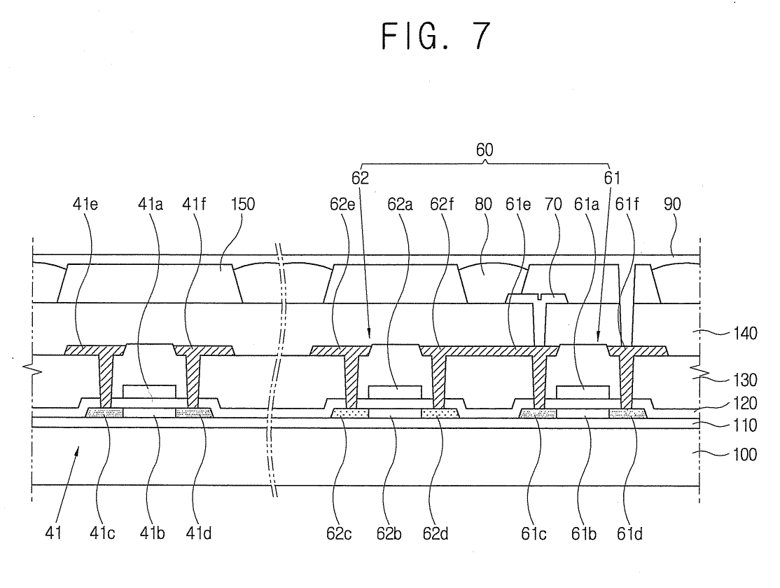

As shown in FIG. 7, the transistors 41, 61 and 62 according to the third embodiment of the present invention have a construction opposite to the transistors in FIG. 3.

Semiconductor layers 41b, 41c and 41d of the switching transistor 41 are p-type semiconductor layers and include an impurity from group 3 of the periodic table, and the transistor 61, a drain electrode 61f of which is connected with the common electrode 90 is provided as p-type transistor.

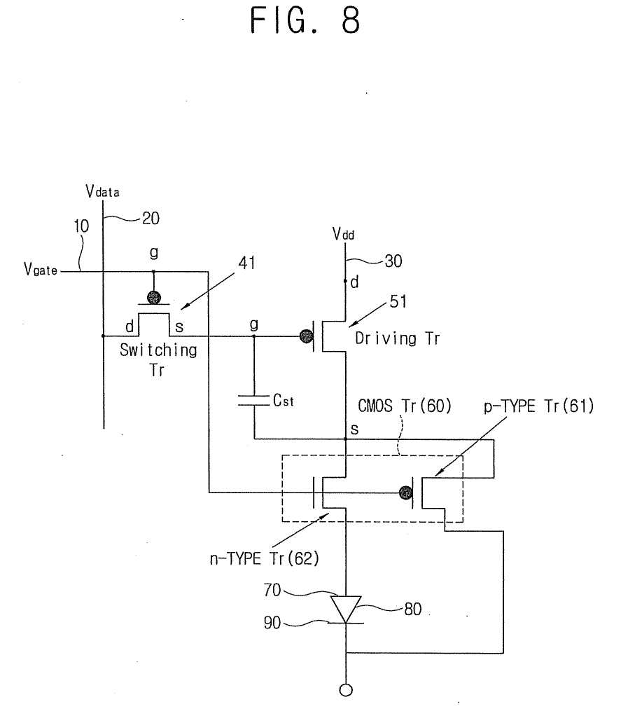

Hereinafter, a fourth exemplary embodiment of a display apparatus according to the present invention will be described with reference to FIG. 8.

As shown in FIG. 8, a fourth exemplary embodiment of a display apparatus according to the present invention includes transistors 41, 51 and 60 having the same type as the transistors in FIG. 5. An n-type transistor 62 is connected in series with a driving transistor 51. Also, the n-type transistor 62 is connected between the driving transistor 51 and a pixel electrode 70. A p-type transistor 61 is connected between a source electrode s of the driving transistor 51 and a common electrode 90.

When a gate on voltage is supplied to a switching transistor 41, the p-type transistor 61 is turned on, and the voltage of the common electrode 90 is supplied to the source electrode s of the driving transistor 51. When a gate off voltage is supplied to the switching transistor 41, the n-type transistor 62 will be turned on, and a driving voltage V_{dd} will be transmitted to the driving transistor 51.

When the gate off voltage is supplied and the p-type transistor 61 is turned on, the driving transistor 51 and the p-type transistor 61 act similar to resistors between a power supply line 30 and the common electrode 90. In one exemplary embodiment the channel of the p-type transistor 61 is widened to minimize the resistance thereof. Accordingly, a large amount of current can flow through the wide channel so that substantially all of a common voltage can be supplied to the output terminal s of the driving transistor 51.

As described above, a display apparatus according to the present invention can use a simple structure to decrease the required data voltage, and thereby reduce power consumption of the display apparatus.

Although a few exemplary embodiments of the present invention have been shown and described, it will be appreciated by those skilled in the art that changes may be made in these exemplary embodiments without departing from the principles and spirit of the present invention, the scope of which is defined in the appended claims and their equivalents.

What is claimed is:

1. A display apparatus, comprising:
a switching transistor;
a driving transistor, a control terminal of which is connected to an output terminal of the switching transistor;
a storage capacitor provided between the output terminal of the switching transistor and an output terminal of the driving transistor; and
a complementary metal oxide semiconductor transistor connected in parallel with a control terminal of the switching transistor.

2. The display apparatus according to claim 1, further comprising a power supply line which supplies a driving voltage to the driving transistor,
wherein the complementary metal oxide semiconductor transistor comprises a first transistor, and a second transistor connected in parallel with the first transistor,
the first transistor is one of an n-type transistor and a p-type transistor,
the second transistor is of a type opposite the first transistor, and
the second transistor is connected in series with the driving transistor.

3. The display apparatus according to claim 2, wherein the switching transistor comprises an n-type transistor, and
the second transistor turns off when a high voltage is supplied to the switching transistor.

4. The display apparatus according to claim 3, wherein an input terminal of the second transistor is connected to the power supply line, and an output terminal thereof is connected to an input terminal of the driving transistor.

5. The display apparatus according to claim 4, further comprising a pixel electrode, and a common electrode disposed substantially opposite the pixel electrode,
wherein the first transistor is connected between the common electrode and the output terminal of the driving transistor.

6. The display apparatus according to claim 3, further comprising a pixel electrode, and a common electrode disposed substantially opposite the pixel electrode,
wherein an input terminal of the second transistor is connected to the output terminal of the driving transistor, and an output terminal of the second transistor is connected to the pixel electrode.

7. The display apparatus according to claim 6, wherein the first transistor is connected between the output terminal of the driving transistor and the common electrode.

8. The display apparatus according to claim 3, wherein the switching transistor comprises a semiconductor layer including amorphous silicon.

9. The display apparatus according to claim 3, wherein the switching transistor comprises a semiconductor layer including polysilicon.

10. The display apparatus according to claim 2, wherein the switching transistor comprises a p-type transistor, and
the second transistor turns off when a low voltage is supplied to the switching transistor.

11. The display apparatus according to claim 10, wherein an input terminal of the second transistor is connected to the power supply line, and an output terminal thereof is connected to an input terminal of the driving transistor.

12. The display apparatus according to claim 11, further comprising a pixel electrode, and a common electrode disposed substantially opposite the pixel electrode,
wherein the first transistor is connected between the common electrode and the output terminal of the driving transistor.

13. The display apparatus according to claim 10, further comprising a pixel electrode, and a common electrode corresponding to the pixel electrode,
wherein an input terminal of the second transistor is connected to the output terminal of the driving transistor, and an output terminal of the second transistor is connected to the pixel electrode.

14. The display apparatus according to claim 13, wherein the first transistor is connected between the output terminal of the driving transistor and the common electrode.

15. The display apparatus according to claim 10, wherein the switching transistor comprises a semiconductor layer including polysilicon.

16. The display apparatus according to claim 10, wherein the switching transistor comprises a semiconductor layer including amorphous silicon.

17. A display apparatus, comprising:
a switching transistor;
a driving transistor, a control terminal of which is connected to an output terminal of the switching transistor;
a storage capacitor provided between the output terminal of the switching transistor and an output terminal of the driving transistor; and
a first transistor and a second transistor respectively connected in parallel with a control terminal of the switching transistor,
wherein the first transistor is one of an n-type transistor and a p-type transistor, and the second transistor is of a type opposite the first transistor.

18. The display apparatus according to claim 17, further comprising a power supply line which supplies a driving voltage to the driving transistor,
wherein the second transistor is connected in series with the driving transistor.

19. The display apparatus according to claim 18, further comprising a pixel electrode, and a common electrode disposed substantially opposite the pixel electrode,
wherein the first transistor is connected between the common electrode and the output terminal of the driving transistor.

20. A method of manufacturing a display apparatus, the method comprising:
forming a switching transistor;
forming a driving transistor, a control terminal of which is connected to an output terminal of the switching transistor;
forming a storage capacitor provided between the output terminal of the switching transistor and an output terminal of the driving transistor; and
forming a complementary metal oxide semiconductor transistor connected in parallel with a control terminal of the switching transistor.
